(19) United States
(12) Patent Application Publication
(10) Pub. No.: US 2026/0082830 A1
(43) Pub. Date: Mar. 19, 2026

(54) GUNN DIODES WITH DOPED EPITAXIAL REGIONS

(71) Applicants: Abhishek A. Sharma, Portland, OR (US); Tahir Ghani, Portland, OR (US); Wilfred Gomes, Portland, OR (US)

(72) Inventors: Abhishek A. Sharma, Portland, OR (US); Tahir Ghani, Portland, OR (US); Wilfred Gomes, Portland, OR (US)

(21) Appl. No.: 18/887,164

(22) Filed: Sep. 17, 2024

(51) Int. Cl. H10N 89/00

(52) U.S. Cl. CPC H10N 89/02

(57) ABSTRACT

Gunn diodes are included in a device plane of an integrated circuit device, e.g., a diode array is in the same plane as a transistor array. A Gunn diode includes two highly n-doped regions surrounding a lower-doped n-type region. The highly-doped regions may be formed through epitaxial deposition. A Gunn diode may be arranged as a vertical diode, with two contacts stacked vertically over and under the diode, or as a horizontal diode, with two contacts at opposite horizontal ends of the diode. The Gunn diodes may be formed around a fin, e.g., with a front-side contact over the fin and a back-side contact under the fin.

### BACKGROUND

A Gunn diode, also referred to as a transferred electron device (TED), is a two-terminal device that is characterized by a current-voltage (I-V) curve with a region of negative differential resistance, or more generally, negative impedance. The Gunn diode is based on the Gunn effect, which produces oscillations along the negative differential resistance region. As the electric field applied to the diode increases, the current though the diode initially increases and then decreases in a cyclical manner, leading to periodic fluctuations in current. The current fluctuations produce high-frequency oscillations, typically in the microwave frequencies, e.g., between 300 megahertz (MHz) and 300 gigahertz (GHz).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates a cross-section of a Gunn diode, according to some embodiments of the present disclosure.

FIG. 2 illustrates example I-V curves for Gunn diodes disclosed herein, according to some embodiments of the present disclosure.

FIG. 3 is a cross-section illustrating a first example vertical Gunn diode, according to some embodiments of the present disclosure.

FIG. 4 is a cross-section illustrating a second example vertical Gunn diode, according to some embodiments of the present disclosure.

FIGS. 5A and 5B are two cross-sections illustrating an example set of vertical Gunn diodes formed around semiconductor fins, according to some embodiments of the present disclosure.

FIGS. 6A and 6B are two cross-sections illustrating a second example set of vertical Gunn diodes formed around semiconductor fins with different isolation structures and backside contacts, according to some embodiments of the present disclosure.

FIGS. 7A and 7B are two cross-sections illustrating a third example set of Gunn diodes formed around semiconductor fins with wider backside contacts, according to some embodiments of the present disclosure.

FIGS. 8A and 8B are two cross-sections illustrating a fourth example set of Gunn diodes formed around isolated semiconductor fins, according to some embodiments of the present disclosure.

FIGS. 9A-9C are three cross-sections illustrating a horizontal Gunn diode formed in a device area, according to some embodiments of the present disclosure.

FIGS. 10A-10C are three cross-sections illustrating a horizontal Gunn diode formed in a device area with front-side and back-side contacts, according to some embodiments of the present disclosure.

FIGS. 11A-11C are three cross-sections illustrating a Gunn diode and transistor formed in a device plane, according to some embodiments of the present disclosure.

FIGS. 12A and 12B are top views of a wafer and dies that include one or more Gunn diodes in accordance with any of the embodiments disclosed herein.

FIG. 13 is a cross-sectional side view of an IC device that may include one or more Gunn diodes in accordance with any of the embodiments disclosed herein.

FIG. 14 is a cross-sectional side view of an IC device assembly that may include one or more Gunn diodes in accordance with any of the embodiments disclosed herein.

FIG. 15 is a block diagram of an example computing device that may include one or more Gunn diodes in accordance with any of the embodiments disclosed herein.

FIG. 16 is a block diagram of an example processing device that includes one or more Gunn diodes in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

A diode is a two-terminal device that conducts current in one direction, referred to as the forward direction, while generally blocking current in the opposite direction, referred to as the reverse direction. In the forward direction, current enters through one terminal, which is called the anode, and leaves through the other terminal, which is called the cathode. When at least a minimum voltage, referred to as a forward voltage, is applied to the anode, this turns on the diode and current flows across the diode in the forward direction, from the anode to the cathode. Different types of materials may be used to form a diode. Many semiconductor diodes include a p-n junction, which is an interface between two types of semiconductor materials, p-type and n-type. Semiconductor diodes may include silicon, germanium, or other types of semiconductor materials.

Gunn diodes do not include a p-n junction. Instead, Gunn diodes include a stack of n-doped material, with two highly doped regions (referred to as doped regions or n+ regions) near the terminals, and a lightly doped region (referred to as an n region, active region, or buffer region) between the highly doped region. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with holes as the primary charge carrier is referred to as p-type, and a semiconductor material or semiconductor region with electrons as the primary charge carrier is referred to as n-type. The oscillation effect of a Gunn diode is exhibited in stacks of n-type materials with electron charge carriers.

When a voltage is applied across the lightly n-doped active region, an electric field develops across the active region. Initially, current across the device increases, but after reaching the threshold voltage, the Gunn diode operates in a negative differential resistance region in which the current decreases. After a current pulse exits the device, another pulse is generated by again increasing the voltage. The series of current pulses produces a sustained oscillation at an oscillation frequency, where the frequency may be based on device characteristics, such as thickness of the active region and operating temperature.

In a Gunn diode, one of the n+ regions is generally larger than the other, with the current traveling through the larger n+ region, through the n region, and then though the smaller n+ region. The larger n+ region provides good ohmic contact and low contact resistance with the anode, which ensures efficient carrier injection and provides proper electric field distribution through the device.

Gunn diodes have been used as oscillators for various applications, such as radio frequency (RF) communications, microwave transmitters, military radar, and various sensors. For RF devices, the active region and n+ regions each have a thickness of around a micron. As disclosed herein, semiconductor processing techniques can be used to produce Gunn diodes at much smaller scales and that operate at lower voltages. The Gunn diodes disclosed herein be used in integrated circuit (IC) products, for example, to provide an on-die processor clock, or to provide one or more on-die synchronization clocks to enable frequency matching for multi-die systems.

In some embodiments disclosed herein, Gunn diodes are arranged vertically through a device plane or transistor plane of an IC device, so that current flowing across the active region moves in a direction perpendicular to the device plane. The Gunn diodes have an upper terminal and a lower terminal. The upper terminal may be formed over the wafer or other substrate on which the transistors are formed. The lower terminal may be formed on the back side or under side of the wafer or substrate over which the transistors are formed. For example, a semiconductor fin or pillar may be formed within the substrate or over the substrate, and n+ regions may be epitaxially grown over a top side and a bottom side of the fin or pillar. The substrate is thinned prior to forming the back-side n+ region and contact.

In other embodiments disclosed herein, Gunn diodes are arranged horizontally across a device plane or transistor plane of an IC device, so that current flows across the active region in a direction parallel to the device plane. The Gunn diodes have two terminals on either side of the active region; one or both terminals may be over or under the device plane (i.e., two backside contacts, two frontside contacts, or one backside contact and one frontside contact). An n-type semiconductor fin or one or more n-type nanoribbons may be formed within the substrate or over the substrate, and n+ regions may be epitaxially grown at either end of the fin or nanoribbons.

An IC device includes various circuit elements, such as transistors and, in this case, diodes, that are coupled together by metal interconnects. The circuit elements and metal interconnects may be formed in different layers. In particular, one or more layers of an IC device in which transistors, diodes, and/or other IC components are implemented may be referred to as a “transistor layer” or “device layer”. Layers with conductive interconnects for providing electrical connectivity (e.g., in terms of signals and power) to the transistors and/or other devices of the transistor layer of the IC device may be referred to as a “metal layer,” “metallization layer,” or “interconnect layer”. For example, the device layer may be a front-end-of-line (FEOL) layer, while the metal layers may be back-end-of-line (BEOL) layers formed over the FEOL layer. A set of metallization layers are referred to as a metallization stack. In some embodiments disclosed herein, a first metallization stack is formed over a front side of the device layer, and a second metallization stack is formed over the back side of the IC device, i.e., on an opposite side of the device layer from the first metallization stack. The second metallization stack may be coupled to back-side contacts of the diodes and transistors.

In general, forming device contacts on the back side of the device can provide certain advantages. For example, including both front and back side contacts enables routing on both sides of the device, which can offer different options for forming connections between transistors and/or diodes. Furthermore, including contacts and routing on both sides of the device can also help increase density of transistors. In particular, using vertical diodes with front- and back-side contacts rather than horizontal diodes with two contacts in the same side can lead to increased density of diodes in the IC device; this may enable increasing a number of diodes that may be included and/or reducing the amount of surface area (e.g., wafer area or die area) consumed by diodes.

To fabricate backside contacts, at least some portions of the devices and routing are typically formed over a front side of the wafer, followed by a metallization stack, as described above. The assembly is then flipped, and the wafer is thinned, e.g., by a grinding process, to reveal the back side of the devices. Then, the backside contacts are formed on the back sides of the transistor, followed by one or more back-side metal layers. Removing most or all of the thickness of the wafer can result in a relatively thin IC package. Thus, the vertical diodes with front-side and back-side contacts, described herein, consume a relatively small amount of surface area (e.g., compared to horizontal diodes), and can be fabricated in an IC device with a low height (as a result of thinning the wafer).

As noted above, the Gunn diodes described herein are formed within a device plane. Vertical Gunn diodes include one contact over the device plane and one contact under the device plane. For horizontal Gunn diodes, each contact may be either over or under the device plane. The diode includes three n-type semiconductor regions with different dopant levels; in particular, a middle, active region has a lower dopant concentration is sandwiched between two regions of higher dopant concentration. A pair of terminals, e.g., metal contacts, are each coupled to one of the higher doped regions, forming an anode at one end and a cathode at the other end. One or both of the terminals may be coupled to one or more transistor devices, forming an oscillator that is coupled to a logic circuit in the IC device. In certain embodiments, a Gunn diode is formed in the same layer as a set of transistors. Transistors in the device layer may also include contacts over and under the device plane; for example, in a back-gated transistor, the gate contact may be on the back side. Alternatively, one or both of the source/drain contacts of the transistors may be backside contacts.

The Gunn diodes described herein advantageously be used in low-temperature environments, such as cooled IC devices. In general, when semiconductor devices operate at lower temperatures, they have improved performance. For example, lower temperatures can lead to increased drive currents across transistors, and transistors operating at lower temperatures generally experience lower leakage. In Gunn diodes, a lower temperature leads to a steeper and longer negative differential range, which can improve performance and stability of the Gunn diodes described herein.

Certain embodiments of the Gunn diodes described herein include fin-shaped semiconductors regions forming the bulk semiconductor material for the active region. Semiconductor fins are often used in fin-shaped transistor devices, referred to as FinFET. FinFETs are transistors having a non-planar architecture where a fin, formed of one or more semiconductor materials, extends away from a base (where the term “base” refers to any suitable support structure on which a transistor may be built, e.g., a substrate). A portion of the fin that is closest to the base may be enclosed by an insulator material. Such an insulator material, typically an oxide, is commonly referred to as a “shallow trench isolation” (STI), and the portion of the fin enclosed by the STI is typically referred to as a “subfin portion” or simply a “subfin.” A gate stack that includes at least a layer of a gate electrode material and, optionally, a layer of a gate dielectric may be provided over the top and sides of the remaining upper portion of the fin (i.e., the portion above and not enclosed by the STI), thus wrapping around the upper-most portion of the fin. The portion of the fin over which the gate stack wraps around is typically referred to as a “channel portion” of the fin because this is where, during operation of the transistor, a conductive channel forms, and is a part of an active region of the fin. Two S/D regions are provided on the opposite sides of the gate stack, forming a source and a drain terminal of a transistor. FinFETs may be implemented as “tri-gate transistors,” where the name “tri-gate” originates from the fact that, in use, such transistors may form conducting channels on three “sides” of the fin. FinFETs potentially improve performance relative to single-gate transistors and double-gate transistors.

Other embodiments of the diodes described herein include nanoribbon or nanowire based semiconductors regions forming the bulk semiconductor material. In general, in a nanowire-based transistor or nanoribbon-based transistor (referred to generally as a nanoribbon transistor), a gate stack that may include a stack of one or more gate electrode metals and, optionally, a stack of one or more gate dielectrics may be provided around one or more elongated semiconductor structures called “nanoribbons”, forming a gate on all sides of the nanoribbon or nanoribbons. A portion of a nanoribbon around which the gate stack wraps around is referred to as a “channel” or a “channel portion.” A semiconductor material of which the channel portion of the nanoribbon is formed is commonly referred to as a “channel material.” A source region and a drain region are provided on the opposite ends of the nanoribbon, on either side of the gate stack, forming, respectively, a source and a drain of such a transistor.

The Gunn diodes described herein may be implemented in combination with one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g., logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

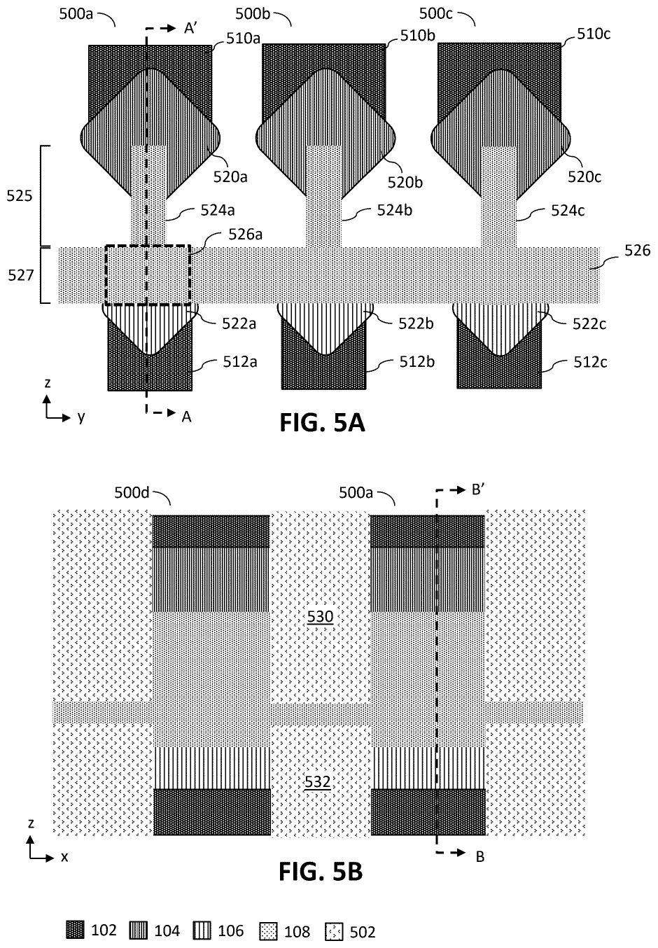

For convenience, if a collection of drawings designated with different letters are present, e.g., FIGS. 5A-5B, such a collection may be referred to herein without the letters, e.g., as “FIG. 5.”

### Example Gunn Diode

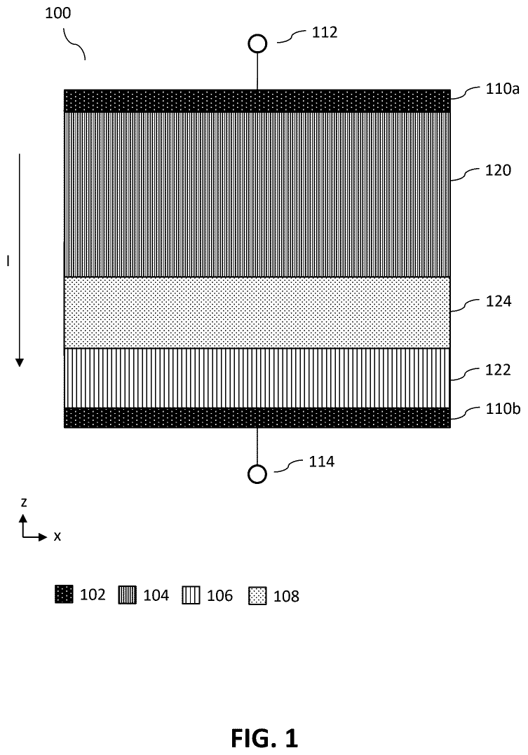

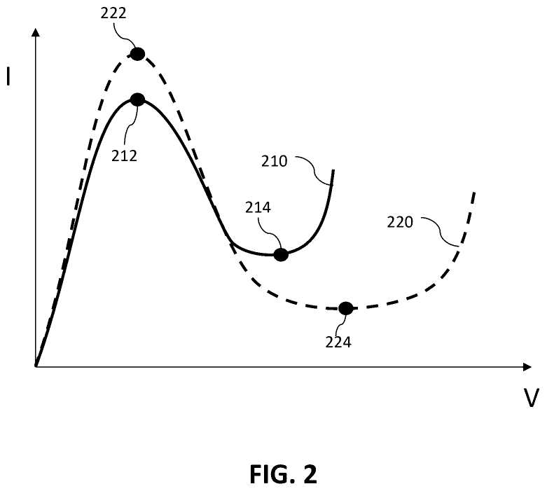

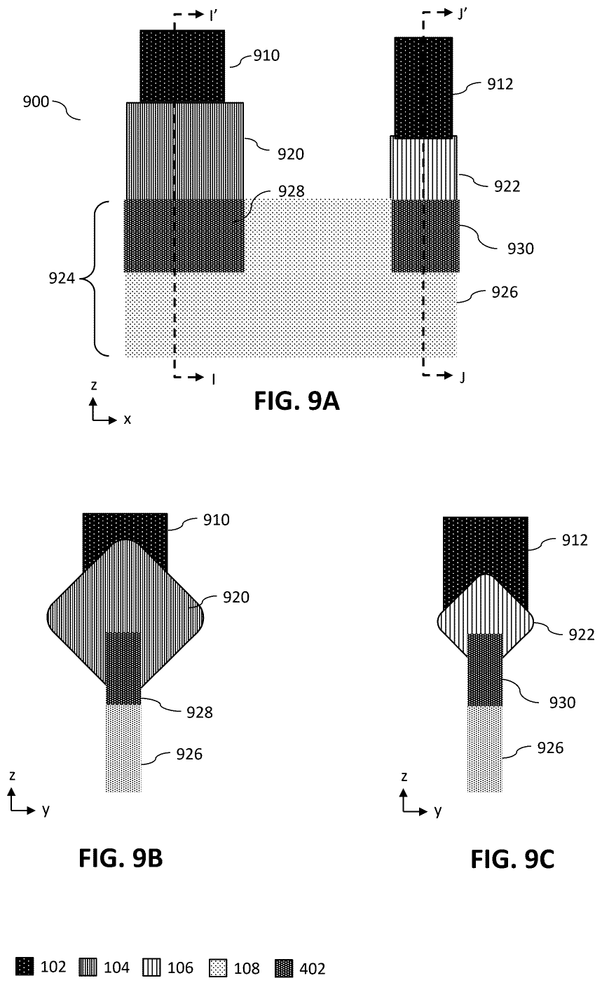

FIG. 1 illustrates a cross-section of a Gunn diode 100, also referred to as a diode 100, according to some embodiments of the present disclosure. The diode 100 may be included in an IC device, as shown in FIGS. 2-11, e.g., along a device plane with transistor devices, as shown in FIG. 9. A number of elements referred to in the description of FIGS. 1-11 with reference numerals are illustrated in these figures with different patterns, with a legend showing the correspondence between the reference numerals and patterns being provided at the bottom of the drawing pages. For example, the legend in FIG. 1 illustrates that FIG. 1 uses different patterns to show a conductor 102, a first n+ material 104, a second n+ material 106, and an active material 108.

The diode 100 includes two layers 110a and 110b of the conductor 102, a first n+ region 120 of the first n+ material 104, a second n+ region 122 of the second n+ material 106, and an active region 124 of the active material 108. The layers 110a and 110b are generally referred to as metal layers, and the layers 120-124 are generally referred to as semiconductor layers. Two terminals 112 and 114 are represented on the metal layers 110a and 110b; in this case, the terminal 112 is the anode, and the terminal 114 is the cathode. The forward direction, from the anode 112 to the cathode 114, is indicated by the arrow labelled I.

The active region 124 may have a thickness or height, measured in the z-direction, on the order of 1 nanometers or 10 nanometers. For example, the active region 124 may have a thickness between 1 nanometer and 100 nanometers, between 1 nanometer and 10 nanometers, between 10 nanometers and 40 nanometers, or in another range. The thickness of the active region 124 may be based at least in part on the bandgap of the active material, e.g., a high-bandgap material may have a smaller thickness (e.g., less than 10 nanometers). Each of the n+ regions 120 and 122 may also have a thickness on the order of 10 nanometers, e.g., between 10 nanometers and 100 nanometers, between 15 nanometers and 50 nanometers, between 20 nanometers and 40 nanometers, or within some other range.

The conductor 102 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the conductor 102 may include one or more electrically conductive alloys, oxides, or carbides of one or more metals.

One or more of the materials 104, 106, and 108 may include a monocrystalline semiconductor, such as silicon or germanium. For example, the active material 108 may be formed from a silicon wafer, and the n+ materials 104 and 106 are more highly doped regions of the wafer and/or doped silicon that has been epitaxially deposited.

In some embodiments, one or more of the semiconductor materials may include a compound semiconductor with a first sub-lattice of at least one element from group Ill of the periodic table (e.g., Al, Ga, In), and a second sub-lattice of at least one element of group V of the periodic table (e.g., P, As, Sb). For some embodiments, one or more of the semiconductor materials may include a III-V material having a high electron mobility, such as, but not limited to InGaAs, InP, InSb, and InAs. For some such embodiments, one or more of the semiconductor materials may be a ternary III-V alloy, such as InGaAs, GaAsSb, InAsP, or InPSb. For some InₓGa₁₋ₓAs embodiments, the In content (x) may be between 0.6 and 0.9, and may advantageously be at least 0.7 (e.g., In_{0.7}Ga_{0.3}As). For other embodiments, one or more of the semiconductor materials may be a group IV material having a high hole mobility, such as, but not limited to Ge or a Ge-rich SiGe alloy. For some example embodiments, one or more of the semiconductor materials may have a Ge content between 0.6 and 0.9, and may be at least 0.7.

In some embodiments, the active material 108 and/or n+ materials 106 and 108 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, one or more of the semiconductor materials may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N-type amorphous or polycrystalline silicon, germanium, indium gallium arsenide, silicon germanium, gallium nitride, aluminum gallium nitride, indium phosphite, and black phosphorus.

In some embodiments, the active material 108 and/or n+ materials 106 and 108 include silicon and carbon (e.g., silicon carbide). In some embodiments, the active material 108 and/or n+ materials 106 and 108 include tungsten combined with one or more of nitrogen, selenium, and sulfur (e.g., tungsten nitride, tungsten diselenide, or tungsten disulfide), or molybdenum combined with one or more of nitrogen, selenium, and sulfur (e.g., molybdenum nitride, molybdenum diselenide, or molybdenum disulfide).

At least a portion of the n+ regions 120 and 122 may be formed using epitaxial growth. In general, epitaxial growth involves crystal growth or material deposition in which crystalline layers are grown over an existing crystal structure, where the grown layers are formed with one or more well-defined orientations with respect to the underlying crystal structure. To form Gunn diodes, the epitaxial growth process is well-controlled and produces crystal layers having a minimal amount of defects.

The materials 104, 106, and 108 of the first n+ region 120, second n+ region 122, and active region 124, respectively, are selected such that the active region 124 has a lower dopant concentration than the first n+ region 120 and second n+ region 122. The first n+ region 120, second n+ region 122, and active region 124 all have the same charge carrier, i.e., n-type charge carriers. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with electrons as the primary charge carrier is referred to as n-type. Doping may be used to create an n-type material; for example, silicon can be doped with another element such that the resulting doped material is n-type. Suitable n-type dopants for one or more of the materials 104, 106, and 108 may include phosphorus, arsenic, antimony, phosphorous, tellurium, sulfur, tin, silicon, germanium, etc.

In general, the active material 108 may have a relatively low level of a dopant, e.g., a lower dopant concentration than the first n+ material 104 and the second n+ material 106. For example, the first n+ material 104 is a highly-doped n-type material, the active material 108 is a lower-doped n-type material, and the second n+ material 106 is a highly-doped n-type material. The active material 108 may have a dopant concentration on the order of 10¹⁶ to 10¹⁸ cm⁻³. The first n+ material 104 and second n+ material 106 may each have a dopant concentration on the order of 10¹⁸ to 10²⁴ cm⁻³. In some embodiments, the dopant concentration of the n+ materials 104 and 106 is at least ten times greater, at least 100 times greater, or at least 1000 times greater than the dopant concentration of the active material 108. In some embodiments, different dopants (e.g., different ones of the phosphorus, arsenic, antimony, etc.) may be included in different ones of the materials 104, 106, and 108. In some embodiments, the active material 108 may have the same dopant as the first n+ material 104 and/or the second n+ material 106, but at a lower concentration. Furthermore, the base material (e.g., silicon, germanium, etc.) for each of these regions may be the same or different. For example, the active material 108 may have a wider bandgap than the n+ materials 104 and 106.

In some embodiments, the n+ regions 120 and 122 have different dopant concentrations. The heights selected for the n+ regions 120 and 122 may be inversely related to the dopant concentrations of the n+ regions 120 and 122. At the anode 112, a relatively large collector has a relatively low dopant concentration, and at the cathode 114, a relatively small emitter has a relatively high dopant concentration. For example, the first n+ region 120, which is larger (as shown in FIG. 1), may have a lower dopant concentration than the second n+ region 122, which is smaller.

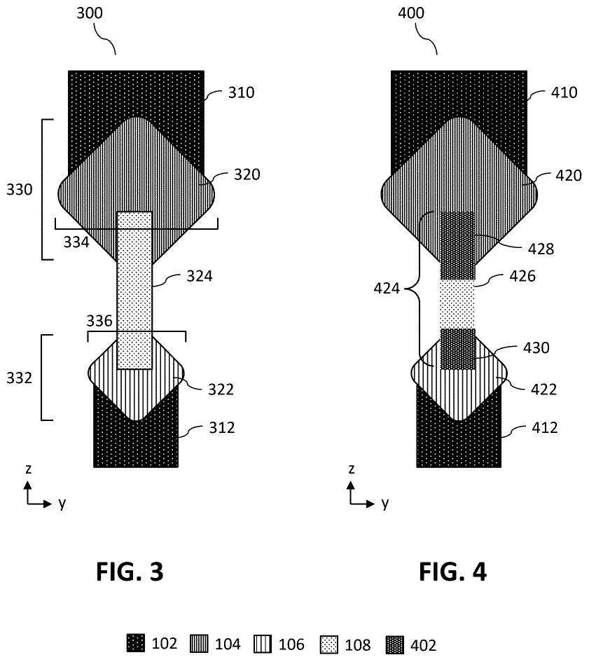

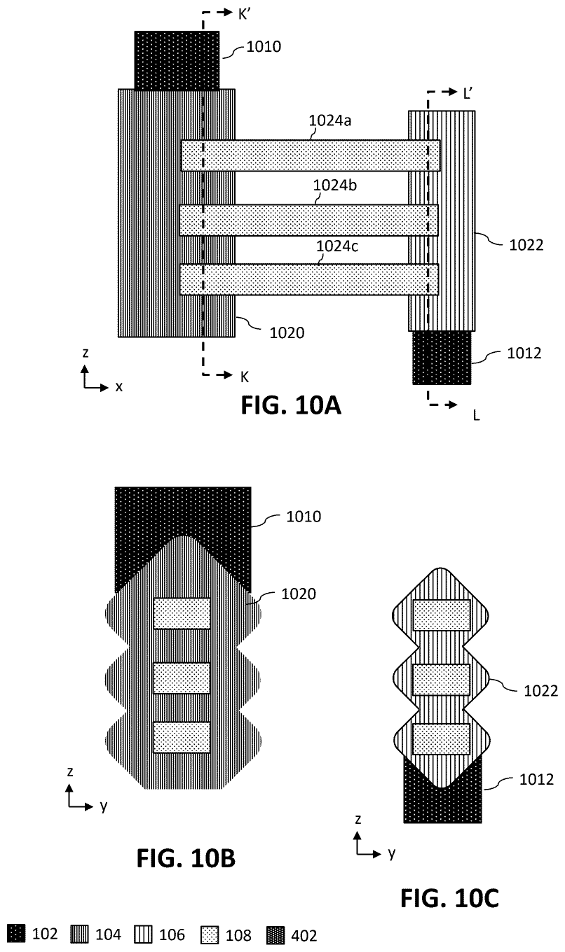

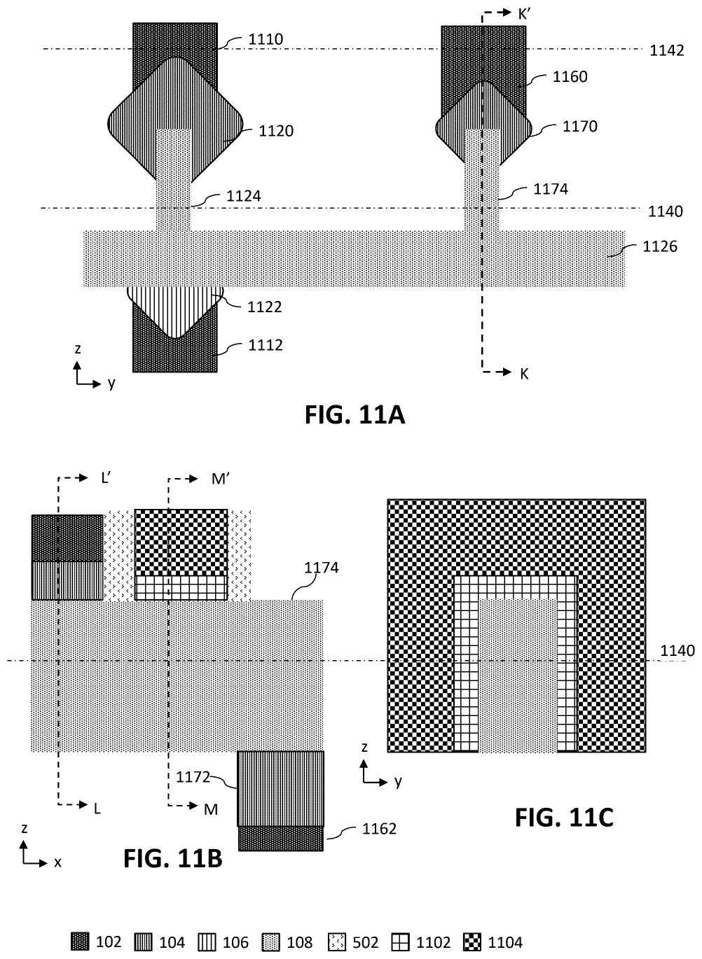

In some embodiments, such as those illustrated in FIGS. 3-9, the Gunn diode 100 extends vertically through a device layer, where the metal layer 110a is a first contact (e.g., a front-side contact) on one side of the device layer, and the metal layer 110b is a second contact (e.g., a back-side contact) on the opposite side of the device layer. An array of multiple similar diodes may be formed across a device layer. In some other embodiments, such as those illustrated in FIGS. 10 and 11, the Gunn diode 100 is oriented horizontally, with the active region 124 arranged horizontally between the first n+ region 120 and second n+ region 122.

### Example I-V Curves for Gunn Diode

FIG. 2 illustrates example I-V curves for the Gunn diodes disclosed herein. FIG. 2 illustrates voltage V along the x-axis and current I along the y-axis. FIG. 2 includes two example I-V curves 210 and 220 of a Gunn diode at different operating temperatures. The Gunn diode has a negative differential resistance region. In general, in a negative differential resistance device, voltage is a single valued function of the current, but the current is a multivalued function of the voltage. Turning first to the curve 210, the negative resistance region for this curve 210 is between the points 212 and 214; in this portion of the curve 210, the current decreases as the voltage increases. The voltage at the point 212 is a threshold voltage Vth for the Gunn diode. When the voltage difference across the Gunn diode increases beyond Vth, the current density starts to decrease. The current further decreases with an increase in the applied voltage. In this region, the device exhibits negative resistance.

When the current pulse enters the active layer (e.g., the active region 124), the voltage difference across the active layer decreases. This prevents another current pulse from passing through the device until the previous current pulse passes through the other end (e.g., through the cathode 114). The voltage difference across the device then rises again, and another pulse begins traversing the active layer. The current continues pulsing in this manner, producing an oscillation at a particular oscillating frequency. If the voltage were further increased, beyond the point 214, which is referred to as the valley voltage or valley point, the current starts increasing again and the device again exhibits positive resistance.

The curve 210 represents device operation at a first temperature. The second curve 220 represents device operation of the same device at a second temperature that is lower than the first temperature. For example, the curve 210 may characterize a device at 300 Kelvin, and the curve 220 may characterize the same device at 100 Kelvin. The negative resistance region for the curve 220 is between the points 222 and 224, where the voltage of the point 222 is the threshold voltage Vth, and the voltage at the point 224 is the valley voltage.

In this example, the threshold voltages of the curves 210 and 220 are the same or substantially the same; in some embodiments, the threshold voltages of the two curves 210 and 220 may be different. The peak current at the threshold voltage of the curve 220 is higher than the peak current at the threshold voltage of the curve 210. In addition, the valley voltage of the curve 220 is higher than the valley voltage of the curve 210, and the current at the valley point 224 is lower than the current at the valley point 214. Furthermore, the curve 210 decreases more sharply or steeply than the curve 220. A Gunn diode may have improved performance at lower temperatures (e.g., at the lower temperature of the second curve 220) as represented by the exaggerated shape of the curve 220 compared to the curve 210.

### Example Cross-Sections of Vertical Gunn Diodes

FIG. 3 is a cross-section illustrating a first example vertical Gunn diode, according to some embodiments of the present disclosure. The diode 300 is formed around a semiconductor fin 324. The semiconductor fin 324 includes the active material 108 and corresponds to the active region 124. The diode 300 further includes a first n+ region 320 and a second n+ region 322, which are formed from the n+ materials 104 and 106, respectively. The first n+ region 320 corresponds to the first n+ region 120 of the diode 100, and the second n+ region 322 corresponds to the second n+ region 122 of the diode 100. The diode 300 further includes a first contact 310 and a second contact 312. The first contact 310 corresponds to the first metal layer 110a of the diode 100, and the second contact 312 corresponds to the second metal layer 110b of the diode 100.

The semiconductor fin 324 is formed in or over a semiconductor substrate, e.g., a semiconductor wafer. The semiconductor wafer may have an initial thickness of, e.g., several hundred microns to over 1 millimeter. After frontside processing, a portion of the semiconductor wafer is thinned, either removing the semiconductor substrate entirely (e.g., as in the example shown in FIGS. 3, 4, and 8), or reducing the thickness of the semiconductor substrate to a few nanometers or a few tens of nanometers (e.g., as shown in FIGS. 5-7). While the semiconductor fin 324 is shown as having a rectangular cross-section in the y-z plane of the reference coordinate system shown, the semiconductor fin 324 may instead have a cross-section that is rounded or sloped at the “top” of the semiconductor fin 324, and the n+ regions 320 and 322 may conform to this shape.

The semiconductor fin 324, as well as the first n+ region 320 and first contact 310, are formed over the semiconductor substrate prior to thinning the semiconductor substrate. For example, after forming the semiconductor fin 324, the first n+ region 320 is grown over the upper end of the semiconductor fin 324, and the first contact 310 is deposited over the first n+ region 320. The semiconductor fin 324 may extend away from the semiconductor substrate and may be substantially perpendicular to the semiconductor substrate. The semiconductor fin 324 may have a height, a dimension measured in the direction of the z-axis of the reference coordinate system, which may, in some embodiments, be between about 20 and 350 nanometers, including all values and ranges therein (e.g. between about 40 and 150 nanometers, between about 75 and 250 nanometers, or between about 150 and 300 nanometers). In some embodiments, the semiconductor fin 324 may have a minimum height of 20 nanometers, 25 nanometers, 30 nanometers, 40 nanometers, or 50 nanometers.

After exposing the lower end of the fin 324 (e.g., by removing the semiconductor substrate), the second n+ region 322 and second contact 312 are formed on the back side of the assembly. In some embodiments, the frontside elements of the diode 300 (i.e., the semiconductor fin 324, first n+ region 320, and first contact 310) are formed, followed by a metallization stack that includes conductive structures coupled to the first contact 310. For example, the conductive structures may couple the first contact 310 to one or more transistor devices, which may be formed in the same layer as the diode 300. The assembly is then flipped, exposing the back side of the semiconductor substrate, which is thinned or removed. The second n+ region 322 and second contact 312 may generally be formed using a similar process to the first n+ region 320 and first contact 310.

The first n+ region 320 and the second n+ region 322 may be formed by epitaxial growth. For example, the first n+ region 320 is epitaxially grown over or around an upper end of the semiconductor fin 324 (i.e., at a first end along the z-axis in the coordinate system shown), and the second n+ region 322 is epitaxially grown over or around a lower end of the semiconductor fin 324 (i.e., at a second, opposite end along the z-axis in the coordinate system shown).

An epitaxial growth process can result in a generally diamond-shaped structure, as shown in the cross-section of FIG. 3, due to the crystallographic orientation of the underlying semiconductor material (e.g., the semiconductor fin 324 and, if present, the semiconductor substrate) and/or the growth process itself. In the example shown, the first n+ region 320 and the second n+ region 322 have rounded diamond shapes in cross-section; this shape is typical of many epitaxial growth processes around semiconductor fins. Specifically, a rounded diamond shape can result because, in an epitaxial deposition process, the growth tends to follow the crystal structure of the underlying structures, with a higher growth rate along certain crystallographic directions compared to others. While the illustrated diamond shape has sides of approximately equal length and rounded right-angles, in other embodiments, the rounded diamond shape may have some variation, e.g., upper sides may be longer than the lower sides (or vice versa), and the upper angle (i.e., the highest angle along the z-direction) may be acute, while the side angles are obtuse (or vice versa).

The n+ regions 320 and 322 have different sizes. In this example, the first n+ region 320 is larger than the second n+ region 322. For example, in the cross-section of FIG. 3, the first n+ region 320 has a larger cross-sectional area than the second n+ region 322. Furthermore, the first n+ region 320 has a height 330, measured in the z-direction, that is greater than a height 332 of the second n+ region 322. The first n+ region 320 also has a width 334, measured in the y-direction, that is greater than a width 336 of the second n+ region 322. In some embodiments, the first n+ region 320 also has a width measured in the x-direction (e.g., into the page in the orientation shown in FIG. 3) that is greater than a width of the second n+ region 322 in the x-direction.

The width in the x-direction and/or y-direction of the n+ regions 320 and 322 (e.g., the widths 334 and 336) may be in the range of 10 to 150 nanometers or a range therein, e.g., between 10 and 50 nanometers, or between 50 and 150 nanometers. The widths 334 and 336 of the n+ regions 320 and 322 may be at least 5 nanometers greater than a width of the semiconductor fin 324 (e.g., a width measured in the y-direction in the orientation shown). The widths 334 and 336 of the n+ regions 320 and 322 may be between 5% larger (i.e., 1.05 times) and 10 times larger than a width of the semiconductor fin 324 or any range therein, e.g., between 5% and 50% larger, between 50% and 100% larger, between 1 and 2 times larger, between 2 and 5 times larger, or between 5 and 10 times larger. The width 334 of the n+ region 320 may be at least 5 nanometers, 10 nanometers, 20 nanometers, or 50 nanometers larger than the width 336 of the n+ region 322. The heights 330 and 332 of the n+ regions 320 and 322 may be in the range of 5 to 200 nanometers or a range therein, e.g., between 5 and 50 nanometers, between 50 and 150 nanometers, or between 100 and 200 nanometers. The height 330 of the n+ region 320 may be at least 5 nanometers, 10 nanometers, 20 nanometers, or 50 nanometers larger than the height 332 of the n+ region 322.

The contacts 310 and 312 also have different sizes, with the first contact 310 being wider than the second contact 312. The increased contact area at the first end (e.g., between the first contact 310 and the first n+ region 320) and the larger first n+ region 320 may reduce contact resistance and improve current injection into the diode 300.

FIG. 4 is a cross-section illustrating a second example vertical Gunn diode, according to some embodiments of the present disclosure. FIG. 4 illustrates a diode 400 that is similar to the diode 300, except that the diode 400 includes a semiconductor fin 424 that has regions with different dopant concentrations. The diode 400 includes a first n+ region 420 and a second n+ region 422, which are formed over the upper end and lower end of the semiconductor fin 424, respectively. The first n+ region 420 and a second n+ region 422 are similar to the n+ regions 320 and 322, respectively, of the diode 300. The diode 400 further includes a first contact 410 and a second contact 412, which are similar to the first contact 310 and the second contact 312 of the diode 300.

The semiconductor fin 424 includes a central region 426 of the active material 108. As noted above, the active material 108 may have a relatively low doping concentration. The semiconductor fin 424 further includes a higher-doped material 402 in an upper region 428 over the central region 426 and in a lower region 430 under the central region 426. The upper region 428 is between the central region 426 and the first n+ region 420, and the lower region 430 is between the central region 426 and the second n+ region 422.

The higher-doped material 402 may have a dopant concentration that is greater than the active material 108 and less than the first n+ material 104 and/or the second n+ material 106. For example, the higher-doped material 402 may have a dopant concentration that is at least one order of magnitude (i.e., ten times) greater than the active material 108, and/or at least one order of magnitude (i.e., ten times) less than the first n+ material 104 and/or the second n+ material 106. In other embodiments, the higher-doped material 402 has a dopant concentration that is the same as or similar to (e.g., on the same order of magnitude of) the first n+ material 104 and/or the second n+ material 106.

The height of the upper region 428 and/or lower region 430 may be between 10% and 500% of the height of the central region 426 or any range therein, where heights are measured in the z-direction in the orientation shown. For example, the height of the upper region 428 and/or lower region 430 may be less than one times the height of the central region 426, at least the same as the height as the central region, or at least twice the height of the central region 426.

While a single higher-doped material 402 is illustrated in FIG. 4, in some embodiments, the upper region 428 and lower region 430 may include different materials, e.g., different n-dopants. Furthermore, in some examples, a semiconductor fin may only include a more highly doped region at one end, while the active material 108 extends to the other end of the semiconductor fin 424. For example, the active material 108 may extend to the lower end of the semiconductor fin 424 (as shown in FIG. 3), while the higher-doped material 402 is at the upper end of the semiconductor fin 424 (as shown in FIG. 4).

The description above and specific examples below discuss semiconductor fins, e.g., semiconductor fins 324 and 424. This generally refers to active material 108 (and, in some cases, higher-doped material 402) having a fin shape that extends in the x-direction and has a generally rectangular cross-section in a x-y cross-section through the active material 108. In other embodiments, the active material 108 and, if present, higher-doped material 402 may have a different shape. For example, the active material 108 may be a square, rounded, or circular pillar that has substantially same width in the x-direction and y-direction.

### Example Arrays of Vertical Gunn Diodes

FIGS. 5A and 5B are two cross-sections illustrating a first set of example diodes 500 formed around semiconductor fins, according to some embodiments of the present disclosure. FIG. 5A illustrates cross-sections through three diodes 500a, 500b, and 500c. Each diode 500 is formed around a respective semiconductor fin 524a, 524b, or 524c, referred to jointly as semiconductor fins 524. Each diode 500 includes a first n+ region 520 (e.g., the first n+ regions 520a, 520b, and 520c of the diodes 500a, 500b, and 500c, respectively) and a second n+ region 522 (e.g., the second n+ regions 522a, 522b, and 522c of the diodes 500a, 500b, and 500c, respectively). The first n+ regions 520 correspond to the first n+ region 120 of the diode 100, and the second n+ regions 522 correspond to the second n+ region 122 of the diode 100. Like the n+ regions 320 and 322 of FIG. 3, the first n+ region 520 is larger than the second n+ region 522. Each diode 500 further includes a first contact 510 (e.g., the first contacts 510a, 510b, and 510c of the diodes 500a, 500b, and 500c, respectively) and a second contact 512 (e.g., the second contacts 512a, 512b, and 512c of the diodes 500a, 500b, and 500c, respectively). The first contacts 510 correspond to the first metal layer 110 of the diode 100, and the second contacts 512 correspond to the second metal layer 110b of the diode 100.

The diodes 500 are similar to the diode of FIG. 3, except that in this example, a portion of a semiconductor substrate 526a remains around the base of the semiconductor fins 524. The semiconductor fins 524 may be considered to include the portion of the semiconductor substrate 526 under the portion of the semiconductor fins 524 that extends upwards from the semiconductor substrate 526. For example, for the diode 500a, the semiconductor fin 524 includes the portion 526a of the semiconductor substrate 526. While the higher-doped material 402 shown in FIG. 4 is not shown at either of the ends of the semiconductor fins 524, in other embodiments, an upper end of the semiconductor fins 524 may include the higher-doped material 402. Alternatively or in addition, some or all of the semiconductor substrate 526 at the base of the semiconductor fins 524 may include the higher-doped material 402.

In this example, the semiconductor fins 524 are formed in or over a semiconductor substrate 526, e.g., a semiconductor wafer. The semiconductor wafer may have an initial thickness of, e.g., several hundred microns to over 1 millimeter. After frontside processing, a portion of the semiconductor wafer is thinned, reducing the thickness 527 of the semiconductor substrate 526 to a few nanometers or a few tens of nanometers, e.g., between 1 and 100 nanometers, between 1 and 40 nanometers, between 1 and 20 nanometers, between 1 and 10 nanometers, between 1 and 5 nanometers, less than 50 nanometers, less than 25 nanometers, less than 10 nanometers, less than 5 nanometers, or within some other range. The semiconductor fins 524, as well as the first n+ regions 520 and first contacts 510, are formed over the semiconductor substrate 526 prior to thinning the semiconductor substrate 526 to the thickness 527. The semiconductor fins 524 extend away from the semiconductor substrate 526 and may be substantially perpendicular to the semiconductor substrate 526. The semiconductor fins 524 may have a height 525, a dimension measured in the direction of the z-axis of the reference coordinate system, which may, in some embodiments, be between about 20 and 350 nanometers, including all values and ranges therein (e.g. between about 40 and 150 nanometers, between about 75 and 250 nanometers, or between about 150 and 300 nanometers). In some embodiments, the semiconductor fin 524 may have a minimum height of 20 nanometers, 25 nanometers, 30 nanometers, 40 nanometers, or 50 nanometers.

A metallization stack that includes conductive structures coupled to the first contacts 510 may further be formed during front-side processing. After flipping thinning the semiconductor substrate 526, the second n+ regions 522 and second contacts 512 are formed on the back side of the assembly, which may include epitaxially depositing the second n+ material 106 as described above. In this example, the n+ regions 522 do not wrap around the ends of the semiconductor fins 524, as illustrated in FIGS. 3 and 4, but instead have flat bottoms along the semiconductor substrate 526. In some embodiments, the thinned semiconductor substrate 526 is doped from the back side to increase the dopant concentration in the portion of the semiconductor substrate 526 adjacent to the regions 522, e.g., to create a region of the higher-doped material 402 at the base of the semiconductor substrate 526.

While not specifically shown in FIG. 5A, one or more dielectric materials may be present between the diodes 500, e.g., between the diodes 500a and 500b and between the diodes 500b and 500c. In some embodiments, a fin trim isolation (FTI) region may be used to isolate individual fins in the x-direction, as illustrated in FIG. 5B. When forming transistor arrays, FTI may be inserted along a gate line, i.e., between two source/drain regions of different transistors. When semiconductor fins, such as the semiconductor fins 524, are used to form diodes, the gate regions may be replaced with FTI regions, thus forming individual vertical diodes along portions of the fins that could be used to form source and drain regions.

More specifically, FIG. 5B illustrates a cross-section through the plane AA′ of FIG. 5A, where the plane AA′ extends through the diode 500a. FIG. 5B illustrates a perpendicular cross-section of the diode 500a, through the x-z plane; FIG. 5A is a cross-section through the plane BB′ of FIG. 5B. FIG. 5B includes an additional diode 500d, which is at a different position in the x-direction from the diode 500a. An array of the diodes 500 (e.g., the diodes 500a-500d) generally extends in the x-direction and y-direction of the coordinate system shown. A region of an IC device that extends in the x-direction and y-direction that includes diodes 500 and, in some cases, other semiconductor devices (e.g., transistors) may generally be referred to as a device area or device plane. An example device plane that includes a diode and a transistor is illustrated in FIG. 9.

The diodes 500a and 500d are separated by two FTI regions 530 and 532, where FTI region 530 is a frontside FTI region, and FTI region 532 is a backside FTI region. The FTI regions 530 and 532 are formed from an isolation material 502, which may generally include low-k or high-k dielectrics including, but not limited to, elements such as hafnium, silicon, oxygen, nitrogen, titanium, tantalum, lanthanum, aluminum, zirconium, barium, strontium, yttrium, lead, scandium, niobium, and zinc. Further examples of the isolation material 502 include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

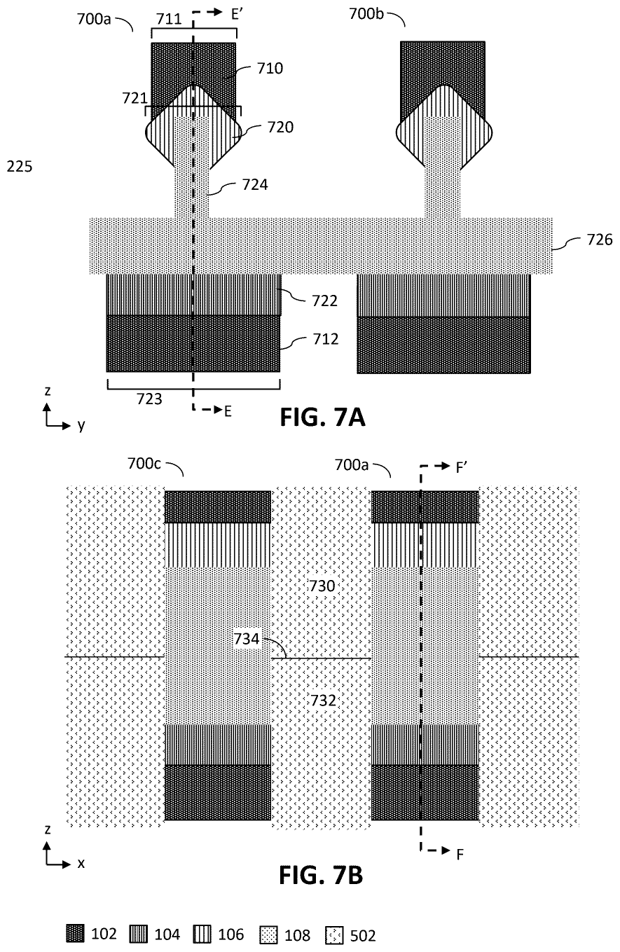

In this example, the frontside FTI regions (e.g., the FTI region 530) are formed after growth of the first n+ regions 520 and, in some cases, after the deposition of the first contacts 510. The frontside FTI regions extend partially through the semiconductor substrate 526. The backside FTI regions (e.g., the FTI region 532) are formed after growth of the second n+ regions 522 and, in some cases, after deposition of the second contacts 512. The backside FTI regions also extend partially through the semiconductor substrate 526, but do not join with the frontside FTI regions, e.g., a portion of the semiconductor substrate 526 remains between the FTI regions 530 and 532. In other embodiments, the frontside and backside FTI regions 530 and 532 meet at a seam, e.g., as shown in FIG. 7B.

As noted above and described with respect to FIG. 3, for each diode 500, the first n+ region 520 is larger than the second n+ region 522, e.g., as shown in FIG. 5A, the first n+ region 520 has a larger height and a larger width in the y-direction than the second n+ region 522. In addition, the first contact 510 is wider than the second contact 512 in the cross-section of FIG. 5A. In FIG. 5B, the first n+ region 520 is depicted as having the same width in the x-direction as the second n+ region 522, and the first contact 510 is depicted as having the same width as the second contact 512. In other embodiments, the first n+ region 520 and first contact 510 may also have larger widths in the x-direction than the second n+ region 522 and second contact 512, and the FTI region 530 adjacent to the first n+ regions 520 may correspondingly have a smaller width than the FTI region 532.

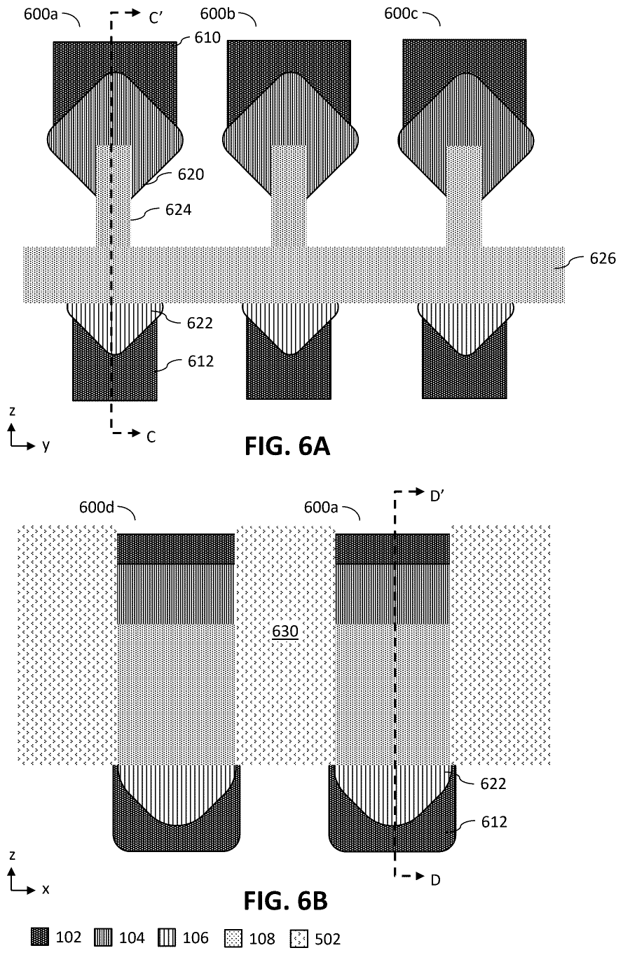

In another embodiment, the frontside FTI regions extend fully through the semiconductor substrate. An example of this is shown in FIGS. 6A and 6B. FIGS. 6A and 6B are two cross-sections illustrating a second set of example diodes 600 formed around semiconductor fins with different isolation structures and backside contacts, according to some embodiments of the present disclosure. FIG. 6B is a cross-section through the plane CC′ in FIG. 6A, and FIG. 6A is a cross-section through the plane DD′ in FIG. 6B.

FIG. 6A illustrates cross-sections through three diodes 600a, 600b, and 600c. Each diode 600 is formed around a respective semiconductor fin, e.g., the semiconductor fin 624 of diode 600a, which is similar to the semiconductor fins 524 of FIG. 5. Each diode 600 includes a first n+ region (e.g., the first n+ region 620 of diode 600a) and a first contact (e.g., the first contact 610 of diode 600a), which are similar to the first n+ regions 520 and first contacts 510 of FIG. 5.

The semiconductor fins (e.g., the semiconductor fin 624) are over and extend away from a semiconductor substrate 626. The semiconductor substrate 626 is similar to the semiconductor substrate 526, described above. However, rather than two opposing FTI regions 530 and 532 cutting partially through the semiconductor substrate 526, as shown in FIG. 5B, a single FTI region 630 extends fully through the portions of the semiconductor substrate 626, as shown in FIG. 6B.

The diodes 600 each further include a second n+ region (e.g., the second n+ region 622 of diode 600a) and a second contact (e.g., the second contact 612 of diode 600a). In the cross-section of FIG. 6A, the second n+ region and the second contacts are similar to the second n+ regions 522 and second contacts 512 of FIG. 5A. In the cross-section of FIG. 6B, however, the second n+ regions have a different shape from the second n+ regions 522 shown in FIG. 5B. In this example, the second n+ regions (e.g., the second n+ region 622) are deposited, e.g., using epitaxial growth, over the semiconductor material (e.g., the semiconductor fin 624) but not over the isolation material 502 of the FTI region 630. In this example, a second dielectric material (not shown in FIG. 6B) may extend between the second contacts of the adjacent diodes 600a and 600d, below the FTI region 630.

In the examples of FIGS. 5 and 6, the frontside or upper n+ region and contact corresponded to the anode side, and the backside or lower+ region and contact corresponded to the cathode side. FIGS. 7A and 7B are two cross-sections illustrating a third example set of diodes 700 formed around semiconductor fins with larger backside n+ regions and larger backside contacts, according to some embodiments of the present disclosure. FIG. 7B is a cross-section through the plane EE′ in FIG. 7A, and FIG. 7A is a cross-section through the plane FF′ in FIG. 7B.

FIG. 7A illustrates cross-sections through two diodes 700a and 700b. Each diode 700 is formed around a respective semiconductor fin, e.g., the semiconductor fin 724 of diode 700a, which is similar to the semiconductor fins 524 of FIG. 5. Each diode 700 includes a first n+ region (e.g., the n+ region 720 of diode 700a) and a first contact (e.g., the first contact 710 of diode 700a), which are similar to the first n+ regions 520 and first contacts 510 of FIG. 5.

The semiconductor fins (e.g., the semiconductor fin 724) are over and extend away from a semiconductor substrate 726. The semiconductor substrate 726 is similar to the semiconductor substrate 526, described above. In this example, between adjacent diodes 700 in the x-direction (e.g., between the diodes 700c and 700a in FIG. 7B), opposing FTI regions 730 and 732 each cut partially through the semiconductor substrate 726, in a similar manner to the FTI regions 530 and 532 of FIG. 5B. However, unlike in FIG. 5B, the two FTI regions 730 and 732 together extend fully through the 726, meeting at a seam, e.g., the seam 734. In other embodiments, two FTI regions 730 and 732 may not meet (e.g., in the FTI arrangement shown in FIG. 5B), or a single FTI region may be used (e.g., as shown in FIG. 6B).

The diodes 700 each further include a second n+ region (e.g., the second n+ region (e.g., the second n+ region 722 of diode 700a) and a second contact (e.g., the second contact 712 of diode 700a). In the cross-section of FIG. 7A, the second n+ region and the second contacts are wider than the second n+ regions 522 and second contacts 512 of FIG. 5A, and wider than the second n+ regions 622 and second contacts 612 of FIG. 6A. Furthermore, the second contact 712 is wider in the y-direction than the first contact 710, and the second n+ region 722 is wider in the y-direction than the first n+ region 720.

FIG. 7A illustrates widths of different features in the x-direction, e.g., in a direction along the shortest dimension of the semiconductor fin 724. In FIG. 7A, the first contact 710 has a width 711, and the first n+ region 720 has a width 721. The width 721 is measured at the widest point of the 720. The second contact 712 and the second n+ region 722 have a width 723, which is greater than the widths 711 and 721.

FIG. 7B illustrates cross-sections of features in the y-direction, e.g., in a direction along the second-shortest dimension of the semiconductor fin 724, which is perpendicular to the shortest direction (i.e., the x-direction) and the longest direction (i.e., the z-direction, or the height). In FIG. 7B, the first contact 710, first n+ region 720, second contact 712, and second n+ region 722 each have a same width in the x-direction. In other embodiments, the second contact 712 and second n+ region 722 may be wider than the first contact 710 and/or the first n+ region 720 in the y-direction.

In the examples shown in FIGS. 5-7, a portion of the semiconductor substrate 526, 626, or 726 remains after thinning, extending under the semiconductor fins 524, 624, or 724, as shown in FIGS. 5A, 6A, and 7A. In other embodiments, the full height of the semiconductor substrate is removed (e.g., by grinding), as shown in FIGS. 3 and 4. Thus, the semiconductor fins are isolated from one another, without a semiconductor material extending between different fins.

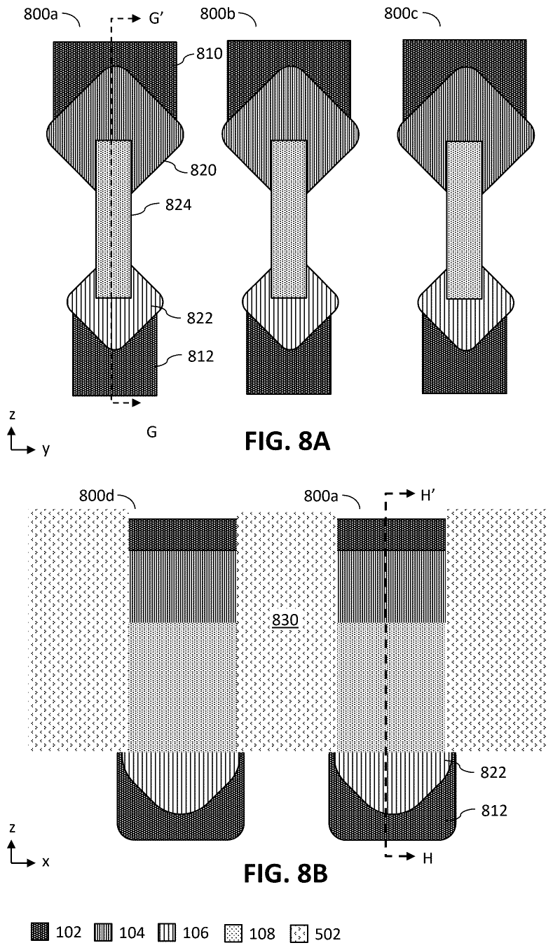

FIGS. 8A and 8B are two cross-sections illustrating a fourth example set of diodes formed around isolated semiconductor fins, according to some embodiments of the present disclosure. FIG. 8B is a cross-section through the plane GG′ in FIG. 8A, and FIG. 8A is a cross-section through the plane HH′ in FIG. 8B.

FIG. 8A illustrates cross-sections through three diodes 800a, 800b, and 800c. Each diode 800 is formed around a respective semiconductor fin, e.g., the semiconductor fin 824 of diode 800a, which is similar to the semiconductor fins 524 of FIG. 5. Each diode 800 includes a first n+ region (e.g., the first n+ region 820 of diode 800a) and a first contact (e.g., the first contact 810 of diode 800a), which are similar to the first n+ regions 520 and first contacts 510 of FIG. 5.

Unlike the embodiments of FIGS. 5-7, the semiconductor fins (e.g., the semiconductor fin 824) are not over a semiconductor substrate. The semiconductor fins may have been formed over a semiconductor substrate, and after fabrication of the first n+ regions, first contacts, and front-side metallization stack (among other structures), the assembly was flipped, and the full semiconductor substrate removed, thus exposing the back side of the semiconductor fins.

The diodes 800 each further include a second n+ region (e.g., the second n+ region 822 of diode 800a) and a second contact (e.g., the second contact 812 of diode 800a). The second n+ regions (e.g., 822) and second contacts (e.g., 812) may generally be formed using a similar process to the first n+ regions and first contacts, e.g., as described above with respect to the first n+ regions and first contacts of FIGS. 3 and 5. In this example, because the first and second n+ regions are formed on either end of the semiconductor fin, the first and second n+ regions (e.g., the regions 820 and 822) have diamond-shaped cross-sections that partially wrap around the ends of the semiconductor fins. As in FIG. 3, the sizes of the first and second n+ regions are asymmetrical, with the first n+ regions (e.g., the n+ region 820) being larger (e.g., wider and taller) than the second n+ regions (e.g., the n+ region 822). In some embodiments, the first and second n+ regions (e.g., the regions 820 and 822) may also have different shapes, e.g., due to different epitaxial growth patterns or crystal structures of the first n+ material 104 and second n+ material 106.

The cross-section of FIG. 8B is similar to the cross-section in FIG. 8B, with a single FTI region 830 extending along the height of the semiconductor fins of the diodes 800d and 800a. In other embodiments, the arrangement of the FTI and the shapes of the second n+ regions and second contacts may have a cross-section similar to that shown in FIG. 5B or FIG. 7B.

FIGS. 5-8 illustrated examples with fin-shaped semiconductor regions. Diodes with fin-shaped semiconductor regions may be fabricated in a device layer that includes FinFETs, e.g., the FinFET shown in FIGS. 9A-9C and described below. If a different transistor architecture is used in the IC device, the active region of the vertical Gunn diode may have different shape. In other words, active region and, in some cases, portions of one or both of the n+ regions (e.g., as shown in FIG. 4) of the vertical diode may have a shape corresponding to the transistor architecture of the IC device. For example, if an IC device includes nanowire or nanoribbon transistors, a vertical Gunn diode may include nanoribbons or nanowires in the active region, rather than a semiconductor fin.

### Example Horizontal Gunn Diodes

The example Gunn diodes illustrated in FIGS. 3-8 were arranged vertically, with the first contact, first n+ region, active region, second n+ region, and second contact arranged in a vertical stack. Current flow through the devices, and in particular, through the active region, is in a vertical direction, e.g., in the z-direction in the example coordinate systems. In other embodiments, Gunn diodes may be arranged horizontally, with current traveling in a horizontal direction, e.g., horizontally across a semiconductor fin or along one or more semiconductor nanoribbons. Two example Gunn diodes with horizontal current flow are illustrated in FIGS. 9 and 10.

FIGS. 9A-9C are three cross-sections illustrating a horizontal Gunn diode formed in a device area, according to some embodiments of the present disclosure. FIG. 9A is a cross-section through a semiconductor fin 924, where the semiconductor fin 924 extends along the x-direction in the coordinate system shown. The fin 924 also extends vertically, e.g., upwards from a substrate that may be under the fin 924 and is not shown in FIG. 9. FIGS. 9B and 9C are cross-sections through the fin 924; specifically, FIG. 9B is a cross-section through the plane Il′, and FIG. 9C is a cross-section through the plane JJ′.

FIG. 9 illustrates one example diode 900. Multiple diodes may be formed across a device area, e.g., as described with respect to FIGS. 5-8. The diode 900 is formed around a semiconductor fin 924. The fin 924 includes an active region 926 that includes the active material 108 and two highly-doped regions 928 and 930 that include the higher-doped material 402. The highly-doped regions 928 and 930 may be similar to the upper region 428 and lower region 430 of FIG. 4, except that the highly-doped regions 928 and 930 are arranged at either end of the semiconductor fin 924 along the x-direction, rather than at either end along the z-direction. In this example, the highly-doped region 928 is larger than the highly-doped region 930, e.g., the highly-doped region 930 is wider in the x-direction. In some embodiments, the highly-doped region 928 is also or alternatively larger than the highly-doped region 930 in the z-direction. In some embodiments, one or both of the highly-doped regions 928 and 930 may be on the back side of the semiconductor fin 924, e.g., as shown in FIG. 10. In other embodiments, the fin 924 may include only the active material 108.

The diode 900 includes a first n+ region 920 coupled to a first end of the semiconductor fin 924 along the x-direction, and a second n+ region 922 coupled to a second, opposite end of the semiconductor fin 924 along the x-direction. In this example, the first n+ region is coupled to the highly-doped region 928, and the second n+ region 922 coupled to the highly-doped region 930. The n+ regions 920 and 922 are similar to the n+ regions of FIGS. 3-8, except that the n+ regions are not vertically stacked, but instead are laterally or horizontally separated from each other, i.e., the first n+ region 920 and second n+ region 922 are offset from each other along the x-direction. The first n+ region 920 is larger than the second n+ region 922, e.g., as described with respect to FIG. 3. The n+ regions 920 and 922 may be formed by epitaxial deposition, as described above. As shown in FIGS. 9B and 9C, the first n+ region 920 extends over and around the highly-doped region 928, and the second n+ region 922 extends over and around the highly-doped region 930. A first contact 910 is coupled to the first n+ region 920, and a second contact 912 is coupled to the second n+ region 922.

FIGS. 10A-10C are three cross-sections illustrating a horizontal Gunn diode 1000 formed in a device area with front-side and back-side contacts, according to some embodiments of the present disclosure. In addition, in contrast to the diode 900, the diode 1000 is formed around a stack of nanoribbons rather than a semiconductor fin.

FIG. 10A illustrates cross-sections through the diode 1000. The diode 1000 is formed around a stack of nanoribbons 1024. Multiple diodes 1000 may be formed across a device area, e.g., as described with respect to FIGS. 5-8. The stack of nanoribbons corresponds to the active region 108. In this example, the stack of nanoribbons includes three nanoribbons 1024a, 1024b, and 1024c. FIGS. 10B and 10C are cross-sections through the ends of the nanoribbons 1024; specifically, FIG. 10B is a cross-section through the plane KK′, and FIG. 10C is a cross-section through the plane LL′.

A first n+ region 1020 is formed around first ends of the nanoribbons 1024a, 1024b, and 1024c on one side of the nanoribbons 1024, and a second n+ region 1022 is formed around second ends of the nanoribbons 1024 at the opposite side, as illustrated in FIGS. 10B and 10C. The n+ regions 1020 and 1022 may be epitaxial regions formed through epitaxial deposition. For example, the first n+ material 104 is grown around the first ends of the nanoribbons 1024; the first n+ material 104 grows outwardly in the x-direction as well as vertically in the z-direction, where the vertical growth shorts regions of the first n+ material 104 together, thus electrically coupling the first ends of the nanoribbons 1024. Likewise, the second n+ regions 1022 short together or electrically couple the second ends of the nanoribbons 1024. The first n+ region 1020 is larger than the second n+ region 1022, e.g., as described with respect to FIG. 3.

While the nanoribbons 1024 illustrated in FIG. 10 include only the active material 108, in other embodiments, one or both ends of the nanoribbons 1024 are more highly doped, e.g., the higher-doped material 402 is present at one or both ends of the nanoribbons 1024.

A first contact 1010 is coupled to the first n+ region 1020, and a second contact 1012 is coupled to the second n+ region 1022. In this example, the first contact 1010 is a frontside contact while the second contact 1012 is a backside contact. In different embodiments, each of the contacts 1010 and 1012 may be either a frontside or a backside contact.

Example Device Plane with Gunn Diode and Transistor Device

The Gunn diodes described herein, e.g., any of the diodes illustrated in FIGS. 3-10, may be included in a device plane or transistor plane of an IC device. In the case of a Gunn diode with one frontside contact and one backside contact (e.g., the diodes illustrated in FIGS. 3-8 and 10), the diode has one terminal over the plane, and the other terminal under the plane. In a horizontal Gunn diode with two frontside contacts, the diode has two terminals over the plane, and in a horizontal Gunn diode with two backside contacts, the diode has two terminals under the plane. One or more other types of semiconductor devices, e.g., one or more transistors, can also be formed within the device plane. FIGS. 11A-11C are three cross-sections illustrating a Gunn diode and transistor formed in a device plane, according to some embodiments of the present disclosure.

FIG. 11A illustrates a diode 1100, which is similar to the diode 500. The diode 1100 may have a cross-section through the x-z plane similar to the cross-sections illustrated in FIG. 5B, for example. The diode 1100 is a vertical Gunn diode, but in other embodiments, the diode 1100 may be a horizontal diode, e.g., the diode 900 or 1000. More generally, in different embodiments, the diode 1100 may be any one of the diodes illustrated in FIGS. 3-10.

FIG. 11A further includes a cross-section through a transistor device 1150. FIG. 11B illustrates a cross-section of the transistor device 1150 through the plane KK′. FIG. 11A is a cross-section through the plane LL′ in FIG. 11B, and FIG. 11C is a cross-section through the plane MM′ in FIG. 11B.

The transistor device 1150 is a FinFET that includes a semiconductor fin 1174, which is similar to the semiconductor fin 524. The semiconductor fin 1174 is formed from the active material 108. The semiconductor fin 1174 extends upwards from a semiconductor substrate 1126, which is similar to the semiconductor substrate 526. The semiconductor substrate 1126 may form a subfin for semiconductor fin 1174 of the transistor 1150. In this example, the semiconductor fin 1174 may be longer than the semiconductor fin 1124 in the x-direction. In some embodiments, e.g., if the diode 1100 is a horizontal diode (e.g., the diode 900), the semiconductor fin 1174 may the same length as the semiconductor fin 1124 in the x-direction. In some embodiments, e.g., if the diode 1100 includes nanoribbons (e.g., as shown in FIG. 10) rather than a semiconductor fin, the transistor 1150 may have a channel region formed from one or more semiconductor nanoribbons.

The transistor device 1150 includes a first source/drain (S/D) region 1170, which is similar to the first n+ region 520 of the diode 500, and a first S/D contact 1160, which may be similar to the first contact 510 of the diode 500. For example, the first S/D region 1170 and first S/D contact 1160 may be fabricated in a same epitaxial deposition process as the first n+ region 520 and first contact 510 of the diode 500. Alternatively, the first S/D region 1170 and first S/D contact 1160 may be fabricated in a separate, but similar, epitaxial deposition process as the first n+ region 520 and first contact 510; for example, as shown in FIG. 11A, the first n+ region 1120 is larger than the first S/D region 1170, indicating that the first n+ region 1120 may have been grown in a separate process from the first S/D region 1170. In such embodiments, the first n+ region 1120 and the first S/D region 1170 may include different materials, rather than the first S/D region 1170 including the first n+ material 104, as shown in FIG. 11. Alternatively, the first n+ region 1120 and the first S/D region 1170 may have similar sizes and materials.

FIG. 11B further illustrates a second S/D region 1172 and a second S/D contact 1162. Here, the first S/D region 1170, first S/D contact 1160 are formed over the front side of the transistor 1150, e.g., over the device plane 1140, while the second S/D region 1172 and second contact 1162 are formed on the back side of the transistor 1150, e.g., under the device plane 1140, described further below. The second S/D region 1172 and second S/D contact 1162 may be formed in a same process as the second n+ region 1122 and second contact 1112 of the diode 1100, or in different processes, as described with respect to the first S/D region 1170.

A device plane 1140 extends through the semiconductor devices 1100 and 1150. The device plane 1140 extends in the x- and y-directions in the coordinate system shown. In this illustration, the device plane 1140 extends through the semiconductor fin 1174 of the transistor device 1150 and the semiconductor fin 1124 of the diode 1100. A contact plane 1142 is over the device plane 1140; the contact plane 1142 extends through the first contact 1110 of the diode 1100 and the first S/D contact 1160 of the transistor 1150. In this example, the first n+ region 1120 and first S/D region 1170 are also over the device plane 1140, but they are below the contact plane 1142. The second n+ region 1122 and second contact 1112 of the diode 1100 are below the device plane 1140, so that the first n+ region 1120 and first contact 1110 are on an opposite side of the device plane 1140 from the second n+ region 1122 and second contact 1112. In different embodiments, different ones of the S/D regions/contacts may be formed over or under the device plane 1140. In some embodiments, one or both of the n+ regions 1120 and/or 1122, as well as one or both of the first S/D region 1170 and second S/D region 1172, may extend into the device plane 1140, e.g., if the diode 1100 is built around one or more nanoribbons (e.g., as shown in FIG. 10) and transistor 1150 is a nanoribbon transistor.

FIGS. 11B and 11C further illustrate the gate stack of the transistor 1150. The gate stack includes a gate dielectric 1102 that wraps around a central portion of the semiconductor fin 1174, and a gate electrode 1104 that wraps around the gate dielectric 1102.

The gate electrode 1104 may include at least one P-type work function metal or N-type work function metal. For a PMOS transistor, metals that may be used for the gate electrode 1104 may include, but are not limited to, ruthenium, palladium, platinum, cobalt, nickel, and conductive metal oxides (e.g., ruthenium oxide). For an NMOS transistor, metals that may be used for the gate electrode 1104 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 1104 may include a stack of two or more metal layers, where one or more metal layers are WF metal layers and at least one metal layer is a fill metal layer.

In various embodiments, the gate dielectric 1102 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 1102 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 1102 during manufacture of the transistor 1150 to improve the quality of the gate dielectric 1102. In some embodiments, the gate dielectric 1102 may have a thickness between about 0.5 nanometers and 3 nanometers, including all values and ranges therein, e.g., between about 1 and 3 nanometers, or between about 1 and 2 nanometers.

In some embodiments, the gate stack (i.e., the gate dielectric 1102 and gate electrode 1104) may be surrounded by a gate spacer, not shown in FIG. 11. Such a gate spacer would be configured to provide separation between the gate electrode 1104 and the source/drain contacts of the transistor 1150 and could be made of a low-k dielectric material, some examples of which have been provided above. A gate spacer may include pores or air gaps to further reduce its dielectric constant.

In the illustrated example, while the first contact 1110, first n+ region 1120, second n+ region 1122, and second contact 1112 are all aligned in the x- and y-directions, forming a vertical device where current travels vertically (e.g., in the z-direction) when the diode 1100 is turned on, in the transistor 1150, the first S/D contact 1160 and first S/D region 1170 are offset from the second S/D region 1172 and second S/D contact 1162 in the x-direction, so that when the transistor 1150 is turned on, current travels horizontally in the x-direction through the transistor 1150.

Furthermore, the fin length of the transistor 1150 (e.g., a dimension of the semiconductor fin 1174 in the x-direction, e.g., the horizontal dimension of the semiconductor fin 1174 in FIG. 11B) may be longer than the fin length of the diode 1100 (e.g., a dimension of the semiconductor fin 1124 in the x-direction, e.g., the horizontal dimension of the semiconductor fins 524 in FIG. 5B). This is because the semiconductor fin 1174 of the transistor 1150 extends under the gate stack, e.g., including the length of two S/D regions and the gate, whereas the semiconductor fin 1124 of the diode 1100 is cut by the FTI region (which, in a transistor device, is positioned where the gate stack is), e.g., the FTI region 530, or any of the other FTI regions shown in FIGS. 5-8.

### Example Devices

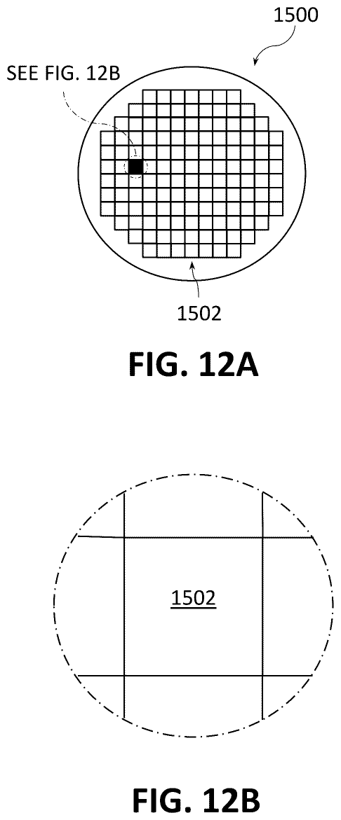

The circuit devices with one or more Gunn diodes disclosed herein may be included in any suitable electronic device. FIGS. 12-16 illustrate various examples of apparatuses that may include the one or more Gunn diodes disclosed herein, which may have been fabricated using the processes disclosed herein.

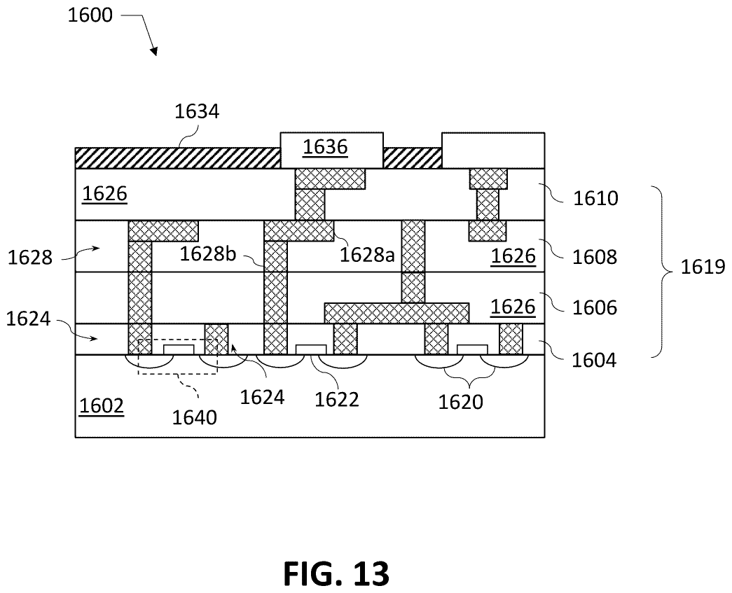

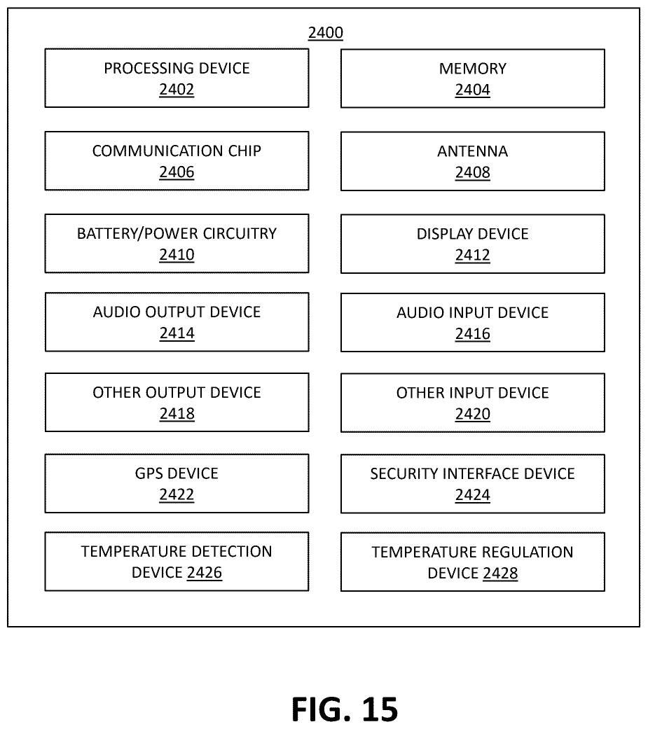

FIGS. 12A and 12B are top views of a wafer and dies that include one or more IC structures including one or more Gunn diodes in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1 and 3-11, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 13, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 15) or other logic that is configured to store information in the memory devices or execute instructions stored in the memory array.

FIG. 13 is a cross-sectional side view of an IC device 1600 that may include one or more Gunn diodes in accordance with any of the embodiments disclosed herein. The IC device 1600 may be formed on a substrate 1602 (e.g., the wafer 1500 of FIG. 12A) and may be included in a die (e.g., the die 1502 of FIG. 12B). The substrate 1602 may be any substrate as described herein. The substrate 1602 may be part of a singulated die (e.g., the dies 1502 of FIG. 12B) or a wafer (e.g., the wafer 1500 of FIG. 12A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 13 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more Gunn diodes at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 13 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 13). Although a particular number of interconnect layers 1606-1610 is depicted in FIG. 13, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 13. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 13. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

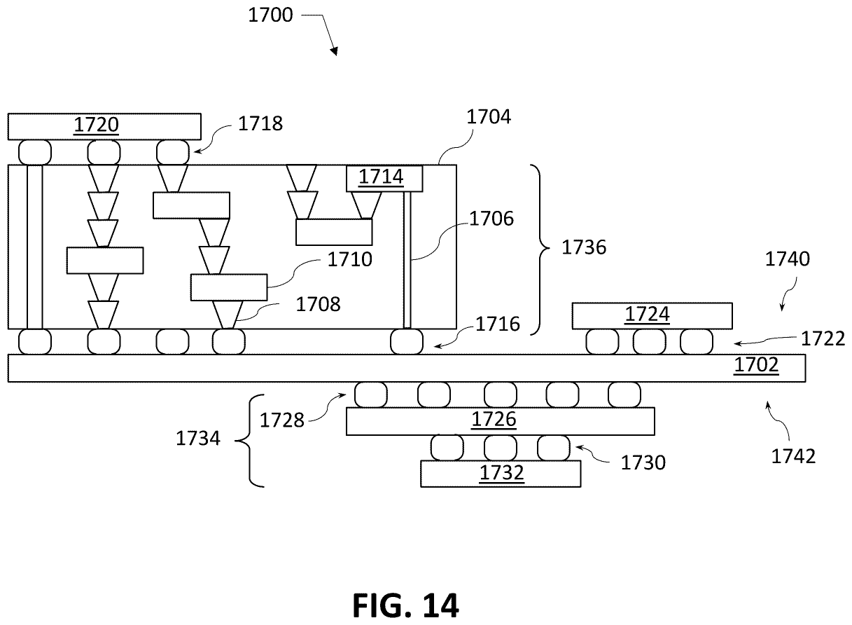

FIG. 14 is a cross-sectional side view of an IC device assembly 1700 that may include components having or being associated with (e.g., being electrically connected by means of) one or more Gunn diodes in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 14 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 14) male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 14, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 12B), an IC device (e.g., the IC device 1600 of FIG. 13), or any other suitable component. In some embodiments, the IC package 1720 may include one or more Gunn diodes, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 14, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 14 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 15 is a block diagram of an example computing device 2400 that may include one or more components including one or more Gunn diodes in accordance with any of the embodiments disclosed herein. For example, any suitable ones of the components of the computing device 2400 may include a die (e.g., the die 1502 of FIG. 12) having one or more Gunn diodes as described herein. Any one or more of the components of the computing device 2400 may include, or be included in, an IC device 1600 of FIG. 13 or an IC device assembly 1700 of FIG. 14.

A number of components are illustrated in FIG. 15 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 15, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404).

Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

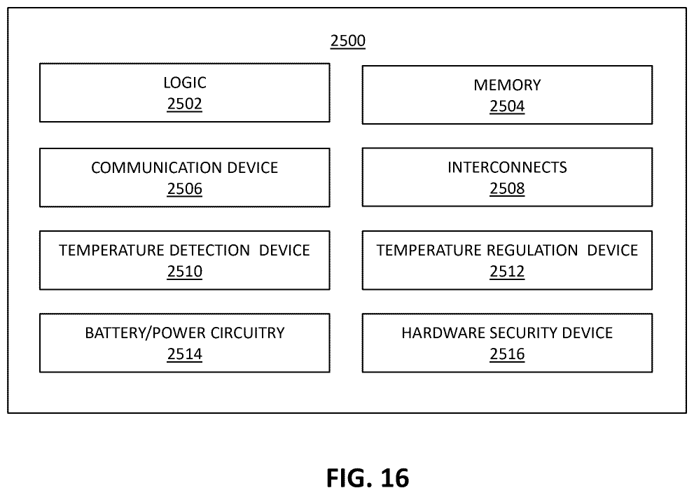

FIG. 16 is a block diagram of an example processing device 2500 that may include one or more IC devices with one or more Gunn diodes in accordance with any of the embodiments disclosed herein. For example, any suitable ones of the components of the processing device 2500 may include a die (e.g., the die 1502 of FIG. 12) having one or more Gunn diodes as described herein. Any one or more of the components of the processing device 2500 may include, or be included in, an IC device assembly 1700 (FIG. 13). Any one or more of the components of the processing device 2500 may include, or be included in, an IC device 1600 of FIG. 13 or an IC device assembly 1700 of FIG. 14. Any one or more of the components of the processing device 2500 may include, or be included in, a computing device 2400 of FIG. 15; for example, the processing device 2500 may be the processing device 2402 of the computing device 2400.

A number of components are illustrated in FIG. 16 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 16, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 15). In some embodiments, the memory 2504 may be a designated device configured to provide storage functionality for the components of the processing device 2500 (i.e., local), while the memory 2404 may be configured to provide system-level storage functionality for the entire computing device 2400 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 15). In some embodiments, the communication device 2506 may be a designated device configured to provide communication functionality for the components of the processing device 2500 (i.e., local), while the communication chip 2406 may be configured to provide system-level communication functionality for the entire computing device 2400 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 15 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 15 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 15. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 15. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

### SELECT EXAMPLES

The following paragraphs provide various examples of the embodiments disclosed herein.

Example 1 provides an integrated circuit (IC) including a device area extending in a first direction and a second direction; and a plurality of devices formed across the device area, where one of the devices includes a semiconductor region having a first end and a second end on opposite sides of the semiconductor region, the first end and the second end arranged along a third direction that is perpendicular to the first direction and the second direction; a first doped region coupled to the first end of the semiconductor region; and a second doped region coupled to the second end of the semiconductor region, the first doped region and the second doped region having a same carrier type.

Example 2 provides the IC device of example 1, where the first doped region and the second doped region are both n-type doped regions, e.g., the first doped region and the second doped region each include an n-type dopant.

Example 3 provides the IC device of example 1 or 2, where the semiconductor region includes an n-type dopant.

Example 4 provides the IC device of any preceding example, where a dopant concentration of the semiconductor region is lower than a dopant concentration of the first doped region.

Example 5 provides the IC device of example 4, where the dopant concentration of the semiconductor region is lower than a dopant concentration of the second doped region.

Example 6 provides the IC device of any preceding example, where the first doped region has a first width along the first direction, the second doped region has a second width along the first direction, and the second width is less than the first width.

Example 7 provides the IC device of any preceding example, where the first doped region has a first height along the third direction, the second doped region has a second height along the third direction, and the second height is less than the first height.

Example 8 provides the IC device of any preceding example, where a cross-section of the first doped region has a rounded diamond shape.

Example 9 provides the IC device of example 8, where the rounded diamond shape is a first rounded diamond shape, a cross-section of the second doped region has a second rounded diamond shape, and the first rounded diamond shape has a larger area than the second rounded diamond shape.

Example 10 provides the IC device of any preceding example, where the semiconductor region has a fin shape, the first end is a top of the fin, and the second end is a base of the fin.

Example 11 provides the IC device of example 10, where the first doped region is epitaxially grown around the top of the fin, and the second doped region is epitaxially grown around the base of the fin.

Example 12 provides the IC device of any preceding example, where the semiconductor region has a first portion including the first end, a second portion including the second end, and a third portion between the first portion and the second portion, where the first portion and the second portion each have a higher dopant concentration than the third portion.

Example 13 provides the IC device of example 12, where the first portion of the semiconductor region has a lower dopant concentration than the first doped region.

Example 14 provides the IC device of any preceding example, where the one of the devices is a two-terminal device.

Example 15 provides the IC device of example 14, where the one of the devices is a Gunn diode.

Example 16 provides the IC device of any preceding example, where the device area further includes a plurality of transistors, and the first doped region is electrically coupled (e.g., conductively coupled, e.g., directly electrically connected) to at least one transistor in the device area.

Example 17 provides a diode including a semiconductor region extending in a first direction, the semiconductor region having a first end and a second end opposite the first end, the first end and second end arranged along the first direction; a first n-type region coupled (e.g., conductively coupled, e.g., directly electrically connected and/or directly physically connected) to the first end of the semiconductor region, the first n-type region having a higher dopant concentration than the semiconductor region; a second n-type region coupled (e.g., conductively coupled, e.g., directly electrically connected and/or directly physically connected) to the second end of the semiconductor region, the second n-type region having a higher dopant concentration than the semiconductor region, where the first n-type region is offset from the second n-type region along the first direction; a first contact coupled (e.g., conductively coupled, e.g., directly electrically connected and/or directly physically connected) to the first n-type region; and a second contact coupled (e.g., conductively coupled, e.g., directly electrically connected and/or directly physically connected) to the second n-type region.

Example 18 provides the diode of example 17, where the semiconductor region is n-type.

Example 19 provides the diode of example 18 or 19, where the diode does not include a conductor around the semiconductor region.

Example 20 provides the diode of any of examples 17-19, where the diode does not include a gate.

Example 21 provides the diode of any of examples 17-20, where the diode is in an integrated circuit (IC) device, the IC device further including a transistor.

Example 22 provides the diode of example 21, where the transistor and the diode are in a device layer of the IC device.

Example 23 provides the diode of example 21 or 22, where the IC device is coupled (e.g., conductively coupled, e.g., directly electrically connected) to a circuit board.

Example 24 provides the diode of any of examples 17-23, where the semiconductor region has a fin shape, the first end is at a first end of the fin, and the second end is at a second end of the fin.

Example 25 provides the diode of any of examples 17-23, where the semiconductor region is a first nanoribbon, the diode further including a second nanoribbon, the first nanoribbon stacked over the second nanoribbon.

Example 26 provides the diode of any of examples 17-25, where the first n-type region is over the first end of the semiconductor region, the second n-type region is over the second end of the semiconductor region and separated from the first n-type region.

Example 27 provides the diode of any of examples 17-25, where the first n-type region is over the first end of the semiconductor region, the second n-type region is under the second end of the semiconductor region.

Example 28 provides an integrated circuit (IC) device including a transistor region including a plurality of transistors, the transistor region along a device plane; a diode region including at least one diode, the diode region along the device plane; and a diode in the diode region, the diode including a semiconductor region having a first end and a second end; a first n-type doped region coupled (e.g., conductively coupled, e.g., directly electrically connected and/or directly physically connected) to the first end; and a second n-type doped region coupled (e.g., conductively coupled, e.g., directly electrically connected and/or directly physically connected) to the second end.

Example 29 provides the IC device of example 28, where the first n-type doped region has a first dopant concentration, the second n-type doped region has a second dopant concentration, and the semiconductor region includes an n-type semiconductor having a third dopant concentration less than the first dopant concentration and less than the second dopant concentration.

Example 30 provides the IC device of example 28 or 29, where the first n-type doped region has a first width, and the second n-type doped region has a second width less than the first width.

Example 31 provides the IC device of any of examples 28-30, where the transistor region includes a transistor having a source or drain (S/D) region, the S/D region and the first n-type doped region within a same second plane, the second plane over the device plane.

Example 32 provides the IC device of any of examples 28-31, further including a first metal region coupled (e.g., conductively coupled, e.g., directly electrically connected) to the first n-type doped region and a second metal region coupled (e.g., conductively coupled, e.g., directly electrically connected) to the second n-type doped region.

Example 33 provides the IC device of any of examples 28-32, where the IC device is coupled (e.g., conductively coupled, e.g., directly electrically connected) to a circuit board.

Example 34 provides an IC package that includes an IC die, including one or more of the IC devices according to any one of the preceding examples. The IC package may also include a further component, coupled to the IC die.

Example 35 provides the IC package according to example 34, where the further component is one of a package substrate, a flexible substrate, or an interposer.

Example 36 provides the IC package according to examples 34 or 35, where the further component is coupled to the IC die via one or more first level interconnects.

Example 37 provides the IC package according to example 36, where the one or more first level interconnects include one or more solder bumps, solder posts, or bond wires.

Example 38 provides a computing device that includes a circuit board; and an IC die coupled to the circuit board, where the IC die includes one or more of the transistor/IC devices according to any one of the preceding examples (e.g., transistor/IC devices according to any one of examples 1-33), and/or the IC die is included in the IC package according to any one of the preceding examples (e.g., the IC package according to any one of examples 34-37).

Example 39 provides the computing device according to example 38, where the computing device is a wearable computing device (e.g., a smart watch) or hand-held computing device (e.g., a mobile phone).

Example 40 provides the computing device according to examples 38 or 39, where the computing device is a server processor.

Example 41 provides the computing device according to examples 38 or 39, where the computing device is a motherboard.

Example 42 provides the computing device according to any one of examples 38-41, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. An integrated circuit (IC) device comprising:
a device area extending in a first direction and a second direction; and
a plurality of devices formed across the device area, wherein one of the devices comprises:
a semiconductor region having a first end and a second end on opposite sides of the semiconductor region, the first end and the second end arranged along a third direction that is perpendicular to the first direction and the second direction;
a first doped region coupled to the first end of the semiconductor region; and
a second doped region coupled to the second end of the semiconductor region, the first doped region and the second doped region having a same carrier type.

2. The IC device of claim 1, wherein the first doped region and the second doped region each include an n-type dopant.

3. The IC device of claim 2, wherein the semiconductor region further includes an n-type dopant.

4. The IC device of claim 1, wherein a dopant concentration of the semiconductor region is lower than a dopant concentration of the first doped region.

5. The IC device of claim 1, wherein the first doped region has a first width along the first direction, the second doped region has a second width along the first direction, and the second width is less than the first width.

6. The IC device of claim 1, wherein the first doped region has a first height along the third direction, the second doped region has a second height along the third direction, and the second height is less than the first height.

7. The IC device of claim 1, wherein a cross-section of the first doped region has a rounded diamond shape.

8. The IC device of claim 7, wherein the rounded diamond shape is a first rounded diamond shape, a cross-section of the second doped region has a second rounded diamond shape, and the first rounded diamond shape has a larger area than the second rounded diamond shape.

9. The IC device of claim 1, wherein the semiconductor region has a fin shape, the first end is a top of the fin, and the second end is a base of the fin.

10. The IC device of claim 1, wherein the semiconductor region has a first portion comprising the first end, a second portion comprising the second end, and a third portion between the first portion and the second portion, wherein the first portion and the second portion each have a higher dopant concentration than the third portion.

11. The IC device of claim 10, wherein the first portion of the semiconductor region has a lower dopant concentration than the first doped region.

12. The IC device of claim 1, wherein the one of the devices is a two-terminal device.

13. The IC device of claim 1, wherein the device area further comprises a plurality of transistors, and the first doped region is electrically coupled to at least one transistor in the device area.

14. A diode comprising:
a semiconductor region extending in a first direction, the semiconductor region having a first end and a second end opposite the first end, the first end and second end arranged along the first direction;
a first n-type region coupled to the first end of the semiconductor region, the first n-type region having a higher dopant concentration than the semiconductor region;
a second n-type region coupled to the second end of the semiconductor region, the second n-type region having a higher dopant concentration than the semiconductor region, wherein the first n-type region is offset from the second n-type region along the first direction;
a first contact coupled to the first n-type region; and
a second contact coupled to the second n-type region.

15. The diode of claim 14, wherein the semiconductor region is n-type.

16. The diode of claim 14, wherein the diode does not include a conductor around the semiconductor region.

17. The diode of claim 14, wherein the diode is in an integrated circuit (IC) device, the IC device further comprising a transistor, and the transistor and the diode are in a device layer of the IC device.

18. The diode of claim 17, wherein the IC device is coupled to a circuit board.

19. An integrated circuit (IC) device comprising:
a transistor region comprising a plurality of transistors, the transistor region along a device plane;
a diode region comprising at least one diode, the diode region along the device plane; and
a diode in the diode region, the diode comprising:
a semiconductor region having a first end and a second end;
a first n-type doped region coupled to the first end; and
a second n-type doped region coupled to the second end.

20. The IC device of claim 19, wherein the first n-type doped region has a first dopant concentration, the second n-type doped region has a second dopant concentration, and the semiconductor region comprises an n-type semiconductor having a third dopant concentration less than the first dopant concentration and less than the second dopant concentration.
